(19) United States
(12) Patent Application Publication
(10) Pub. No.: US 2018/0164165 A1
(43) Pub. Date: Jun. 14, 2018

(54) DEVICES AND METHODS TO STIMULATE MOTION IN MAGNETOELASTIC BEAMS

(71) Applicant: MagCanica, Inc., San Diego, CA (US)

(72) Inventors: Ivan J. GARSHELIS, Dalton, MA (US); Ryan J. KARI, Encinitas, CA (US)

(21) Appl. No.: 15/836,765

(22) Filed: Dec. 8, 2017

Related U.S. Application Data
(60) Provisional application No. 62/431,782, filed on Dec. 8, 2016.

(51) Int. Cl. G01L 1/12; H01L 41/12; G01H 13/00

(52) U.S. Cl. CPC G01L 1/122; G01H 13/00; H01L 41/125; G01L 1/125

(57) ABSTRACT

This invention concerns devices, systems, and methods to induce motion in cantilevers for actuation and sensing applications. Motion is induced by applying current to a ferromagnetic, magnetostrictive cantilever subject to bending stress, and hence strain (deflection), having both elastic and magnetoelastic components. The applied current creates a magnetic field that reorients the magnetoelastic strain component, changing the total strain and thus the total deflection. Changing deflection can be harnessed for actuation or work. Moreover, considering both static and dynamic deflection, measureable parameters that are associated with beam deflection, vibration frequency, and/or amplitude can be measured.

### RELATED APPLICATION

This application claims the benefit of, and priority to, U.S. provisional patent application Ser. No. 62/431,782, filed 8 Dec. 2016, entitled, “Stimulating Vibration in Magnetoelastic Members by the Circumferential Fields of Conducted Currents”, the contents of which are hereby incorporated by reference in their entirety for any and all purposes.

### FIELD OF THE INVENTION

The present invention relates to devices and methods to stimulate motion in cantilevered beams. Specifically, the present invention relates to devices and methods of stimulating motion by an applied conducted current to a beam under bending stress reorienting a component of magnetoelastic strain to be used for producing motion or sensing a portion of the stress or subsequent deflection.

### BACKGROUND OF THE INVENTION

The following description includes information that may be useful in understanding the present invention. It is not an admission that any such information is prior art, or relevant, to the presently claimed inventions, or that any publication specifically or implicitly referenced is prior art.

### BACKGROUND OF THE INVENTION

The act of converting one form of energy to another, defined as transduction, is fundamental to nearly all machinery and electronics. Forms of transduction include the conversion of electricity into: motion (e.g., electric motors), light (e.g., LEDs), and heat (inefficiencies and/or through resistance, as can be used, for example, the to heat or cool an object). Other types of transduction include those related to magnetoelastics. One property associated with magnetoelastics is magnetostriction, or the transduction between applied magnetic field and strain, first reported by Joule in 1842. The Guillemin effect, another magnetoelastic effect, was reported in 1846, as the observed rising of the free end of a 1 cm diameter, “20 or 30 cm” long iron bar (configured as a cantilever beam) to which a weight was attached (the other end being fixed), when an electrical current from a battery was passed through an insulated solenoid wound directly on the bar. Guillemin noted that the weighted end repeatedly rose when current flowed and fell when it ceased, an observation now acknowledged as the discovery of the “ΔE effect” (Bozorth 1993).

Mechanical configurations that make use of the unique attributes of beams, and in particular cantilevered beams, are often combined with transduction. Cantilevers, and systems including cantilevered beams, can be designed to make use of either static or dynamic deflection and the associated attributes of dynamic deflection such as natural frequency (or frequencies) and peak-to-peak deflection. Deflection is often measured statically to serve as a measurement of bending stress acting on the beam, in which sources of bending stress include but are not limited to: surface stress on the beam, forces acting on the beam such as those arising from masses acted upon by gravity, or forces acting on the beam originating from an external body. Dynamic deflection is also often used, in which the natural frequency (or frequencies) of the system of which the beam is a part can act to either build up considerable energy through oscillatory motion, or be used as a sensitive indicator of parameters such as the mass of the system. The combination of cantilevered beams and transduction has led to a tremendous number of scientific and commercial applications. These applications include sensitive laboratory equipment, such as:
Scanning and atomic force microscopy, which allow the surface of solids to be mapped with atomic resolution, such as that described in U.S. Pat. No. 4,724,318 and references including a text by Meyer, Hug and Bennewitz 2004.
Applications in biotechnology and other scientific fields, in which applications often use a treatment on the cantilever (or region thereof) that confer properties that allow it to bind to target molecules. These targets include chemicals or compounds such as explosives; toxins; DNA, antigens, and/or other useful biomarkers, etc. in vapor or liquid phases or on exposed surfaces. As the target binds to the treated region, the effective mass of the cantilever changes, resulting in a change in the natural frequency of the cantilever as well as a change in the surface stress and subsequent static deflection of the cantilever. Examples of these applications and related devices and transducers are documented in numerous papers and patents, examples of which include: U.S. Pat. No. 5,719,324, which uses a piezoelectric effect to induce motion, U.S. Pat. No. 8,122,761, which uses a piezo-resistive effect to serve as a measurement of surface stress, and U.S. Pat. No. 6,523,392, which places the cantilever itself in contact with a sensing element, in which the sensing element volumetrically expands or contracts in the presence of the target, which acts to provide a displacement to the cantilever. Each of these methods detects the bending moment and/or resonance frequency. Methods of measuring deflection include optical methods, such as the use of an optical lever technique to detect movement of a laser beam path in response to deflection; measurement of resistance and/or impedance and include the use of piezo-resistive materials attached to the cantilever; and indirect methods such as using the position of the cantilever to produce a change in capacitance or inductance.
Standard commercial items such as accelerometers, which are ubiquitous on cars, cellphones, and guidance systems. An example of such a design is described by U.S. Pat. No. 4,736,629, which provides an output signal for measuring changes capacitance in response to an applied acceleration.

In each of these examples, cantilevers are used in conjunction with transduction, such as converting motion into an electrical signal either directly (such as using cantilever deflection to cause a change in resistance) or indirectly (such as using an optical method to deflect the path of a light beam or laser beam focused on the cantilever). While many of the fundamental effects were discovered more than 150 years ago, a new form of transduction between the deflection of a cantilever beam and an internally conducted electrical current is expected to benefit both existing applications and those for which its novel features may be uniquely suited.

### DEFINITIONS

Before describing the instant invention in detail, several terms used in the context of the present invention will be defined. In addition to these terms, others are defined elsewhere in the specification, as necessary. Unless otherwise expressly defined herein, terms of art used in this specification will have their art-recognized meanings.

The terms “measure”, “measuring”, “measurement” and the like refer not only to quantitative measurement of a particular variable, but also to qualitative and semi-quantitative measurements. Accordingly, “measurement” also includes detection, meaning that merely detecting a change, without quantification, constitutes measurement.

A “patentable” process, machine, or article of manufacture according to the invention means that the subject matter satisfies all statutory requirements for patentability at the time the analysis is performed. For example, with regard to novelty, non-obviousness, or the like, if later investigation reveals that one or more claims encompass one or more embodiments that would negate novelty, non-obviousness, etc., the claim(s), being limited by definition to “patentable” embodiments, specifically exclude the unpatentable embodiment(s). Also, the claims appended hereto are to be interpreted both to provide the broadest reasonable scope, as well as to preserve their validity. Furthermore, if one or more of the statutory requirements for patentability are amended or if the standards change for assessing whether a particular statutory requirement for patentability is satisfied from the time this application is filed or issues as a patent to a time the validity of one or more of the appended claims is questioned, the claims are to be interpreted in a way that (1) preserves their validity and (2) provides the broadest reasonable interpretation under the circumstances.

### SUMMARY OF THE INVENTION

The object of the invention is to provide a method (or methods) and systems for inducing motion in cantilevers for actuation and sensing applications. The method of inducing motion is through applied current to a cantilever with applied bending stress and subsequent strain (deflection), in which the strain is comprised of both elastic and magnetoelastic components. The applied current creates a magnetic field that reorients the magnetization and thus the magnetoelastic strain component changing the total strain and thus the total deflection. Considering both static and dynamic deflection, the cantilever includes an optional measureable physical property that changes as a function of deflection, allowing static deflection and/or dynamic parameters such as frequency of vibration and associated amplitude to be measured, in which the measureable property includes but is not limited to a measurement of the emf induced within the cantilever. It is an object of the invention that the deflection of the cantilever can be used for actuation or carrying out work. As the change in deflection for an applied current is a function of the applied bending stress, it is also an object of the invention that the change in deflection associated with the application of applied current can be used as a sensed parameter of the magnitude of the bending stress applied. As cantilevers can be configured such that the bending stress applied to a cantilever is a function of a parameter of interest, quantifying the change in deflection for an applied current might be used to quantify the parameter of interest.

Other features and advantages of the invention will be apparent from the following drawings, detailed description, and appended claims.

### BRIEF DESCRIPTION OF THE DRAWINGS

FIG. 1 contains an illustration and a plot. FIG. 1 (a) contains an illustration of a cantilever beam of length L, with diameter D (for a circular cross section), deflected from its originally straight shape (dashed line) to the curved shape (bold solid line) by the gravitational force, W, on the mass m at its free end, with optional composite or treated surface. FIG. 1 (b) is a plot of linear variation of bending moment B with position x.

FIG. 2 contains an illustration of the distribution of tensile and compressive stresses on beam cross sections at indicated distances x from the fixed end (x=0) and indicated distances c from the neutral axes (c=0), in which the beam is configured as per FIG. 1. Stress amplitude is indicated by the relative length of the depicted vectors. The dashed lines indicate the variation of c with x of arbitrary, but constant amplitude tensile stresses, σₑ, having relative amplitudes of 1:2:3. A (not shown) symmetrical distribution of equal amplitude compressive stresses also exists on the −c side of the neutral axes.

FIG. 3 contains two plots showing calculations of the magnetic field components originating from current conducted through a member with rectangular cross section with 25.4 mm width and 3.175 mm thickness for 1 Ampere of current. FIG. 3 (a) is a plot of the magnetic field in the ‘x’ direction, or in the direction of the width of a conductor, with ‘y’ located at the outer most surface of the conductor. FIG. 3 (b) is a plot of the magnetic field in the ‘y’ direction, or in the direction of the thickness of the conductor, with ‘x’ located at the center of the width of the conductor.

FIG. 4 is an illustration of an experimental setup consisting of dual cantilevered beams supporting a single mass.

FIG. 5 is an illustration indicating the different positions of a mass fixed to a cantilevered beam versus its oscillation amplitude.

FIG. 6 contains a flow diagram showing the architecture of a cantilevered system in open loop.

FIG. 7 contains a flow diagram showing the architecture of a cantilevered system in closed loop with a data recording device monitoring the motion dependent device and input signals.

FIG. 8 shows four graphs in which current is applied using feedback based on measured position. The configuration used parallel cantilever beams such as that in FIG. 4 in which the beams were manufactured from oriented Silicon Steel rolled in the longitudinal direction with rectangular cross-section 0.5 mm×2 mm. FIG. 8 (a) shows position versus time. FIG. 8 (b) zooms into the time from 21 to 22 seconds to show the sinusoidal motion. FIG. 8 (c) is current versus time. FIG. 8 (d) shows the current versus time from 21 to 22 seconds.

FIG. 9 contains a plot of the variation of vibration frequency and stroke with beam length for Kanthal 70 in a stretched and straightened condition with a comparison to a calculated frequency using E=157.6 GPa and geometry provided.

FIG. 10 contains a plot of the stroke versus applied peak current for Kulgrid 28 in a stretched and straighten condition and an annealed condition for the geometry provided.

FIG. 11 contains a plot of stroke versus applied peak current for Vacoflux 50 for two different lengths and weights.

FIG. 12 contains a plot of the variation in the peak velocity and peak kinetic energy of the experimental vibrating mass for the beams reported on in FIG. 11.

FIG. 13 contains two plots. FIG. 13 (a) is a plot of measured position and calculated peak stress acting on a parallel cantilever configuration using rectangular cross sectioned beams manufactured from silicon steel versus time versus time. FIG. 13 (b) is a plot of measured emf across the parallel cantilever configuration versus time, in which the cantilevers featured remanent circumferential magnetization.

FIG. 14 contains two plots. FIG. 14 (a) is a plot of measured position and calculated peak stress acting on a parallel cantilever configuration using rectangular cross sectioned beams manufactured from silicon steel versus time versus time versus time. FIG. 14 (b) is a plot of measured emf across the parallel cantilever configuration versus time, in which the cantilevers featured remanent circumferential magnetization.

FIG. 15 contains an illustration of a cantilever fixed at two ends with mass in center.

FIG. 16 contains three plots. FIG. 16 (a) is a plot of a deflection curve for a cantilever fixed at both ends, with a constant modulus of elasticity, E, and with a modulus of elasticity, E, that varies with the applied stress due to a simulated applied current. FIG. 16 (b) is a plot of stress as a function of length along the cantilever (starting from a fixed end). FIG. 16 (c) is a plot of the simulated modulus of elasticity, E, in GPa, as a function of the length of the beam due to a simulated applied current.

FIG. 17 contains two illustrations. FIG. 17 (a) demonstrates a mass held within a frame by a cantilever on each side of the mass. FIG. 17 (b) demonstrates a mass held within a frame with multiple cantilevers connected to the mass.

FIG. 18 is a flow diagram showing the architecture of a cantilevered system in closed loop with a data recording device monitoring the motion dependent device and input signals, and the cantilever being used to carry out mechanical work

FIG. 19 contains an illustration of a ‘V’ shaped cantilever with optional surface treatment and mass.

FIG. 20 contains an illustration of a cantilever with distributed load, such as a flow acting on a surface.

FIG. 21 contains two illustrations. FIG. 21 (a) contains an embodiment in which a cantilever is fixed at two ends to blocks, in which the blocks are attached to a separate member under bending stress. FIG. 21 (b) contains an embodiment in which a cantilever is fixed at two ends to blocks, in which the cantilever is not a straight length but is configured to induce a bending stress based on a linear deflection of a member.

As those in the art will appreciate, the following detailed description describes certain preferred embodiments of the invention in detail, and is thus only representative and does not depict the actual scope of the invention. Before describing the present invention in detail, it is understood that the invention is not limited to the particular aspects and embodiments described, as these may vary. It is also to be understood that the terminology used herein is for the purpose of describing particular embodiments only, and is not intended to limit the scope of the invention defined by the appended claims.

### DETAILED DESCRIPTION

The present invention describes devices and methods for inducing motion in cantilevers for actuation and sensing applications.

### Introduction

This invention is based on the now well understood ΔE effect (Bozorth 1993, 684 to 689). The rationale leading to the invention was that it seemed reasonable to hypothesize that a typically elongate and originally straight member of isotropic ferromagnetic and magnetoelastic, unmagnetized material (including a composite of such materials), if, while deflected under the action of a bending moment, has a portion of its total strain contributing to the deflection arise from a magnetoelastic component. While the Guillemin effect described that a member in this arrangement would stiffen under an applied longitudinal magnetization, such as that from a solenoid wrapped around the member, there was no reference that described what would happen if a circumferential magnetization is applied, such as that from an applied current conducted through the member (or a portion thereof). The inventors hypothesized and have shown that such a member, when subjected to a magnetic field sufficiently intense to significantly alter the orientation distribution of local moments, will experience a change in at least some portion of the magnetostrictive strain (a manifestation of the ΔE effect), which had been contributing to the original deflection, whether the field was axially oriented (longitudinal) as described by Guillemin in 1846, or circumferential such as that from an applied current conducted through the member itself. Thus, if the described member is configured as a horizontal cantilever beam, fixed at one end and deflected by the bending moment associated with a weight attached, for example, to its free end, it will, upon application of the above characterized field, show a change in its deflection. Without wishing to be bound to any particular theory, the following description represents what is believe to be the basis for this discovery. While the description will generally focus on a simple cantilever for clarity in the explanation and validation of the theory, it will be shown that the invention is applicable to any configuration of beam(s) in which a bending moment is applied, generating bending stresses that can be acted upon and reoriented by conducted currents through the member.

### The ΔE Effect

It is well known (Cullity and Graham 2009, 283) that the collinear strain, c, resulting from a uniaxial stress, σ, associated with the application of a force to an isotropic ferromagnetic member having nonzero saturation magnetostriction, λ_{S}, contains a magnetoelastic component, ϵₘ, in addition to the always present elastic component, ϵₑ, thus ϵ=ϵₑ+ϵₘ. Although ϵₑ and ϵₘ both reflect changes in interatomic distances in response to stress, these respective changes manifest two physically distinct natural phenomena and respond quite differently to σ. ϵₑ typically varies linearly with σ at a material dependent rate (a relationship known as Hooke's Law (Gere and Timoshenko 1997, 22)), whereas other than sharing algebraic sign (and being material dependent), ϵₘ has no similarly rigorous dependence on σ. In contrast the variation of ϵₘ with σ is typically non-linear, asymmetric between tensile and compressive stresses, hysteretic, and has unique saturation values. If λ_{S} is positive, λ_{S} reaches its fully saturated value under tensile stress, but half this value (λ_{S}/2) under compressive stress. If λ_{S} is negative, it will reach its fully saturated value under compressive stress, but half this value under tensile stress (absolute(λ_{S})/2).

Moreover, and most notably, ϵₘ (but not ϵₑ) also varies with the orientation (but not polarity) of the local (i.e., domain) magnetization, M_{S}. The orientation of M_{S} at angle θ relative to σ, derives from the minimization of the sum of free energy densities associated with the misalignments from the favored orientations of each of the orientation influencing factors. Thus, (assuming for simplicity that each is uniaxial, and λ_{S} is isotropic), stress anisotropy, (3λ_{S}σ/2), competes with magnetocrystalline anisotropy (K₁), magnetostatic anisotropy (M_{S}H), and possible other sources of structural, residual stress, and shape anisotropy to determine θ. Since the orientations of ϵₘ and M_{S} are fundamentally coupled by the magnetoelastic interaction, ϵₘ is also found to vary with θ as ϵₘ=3λ_{S}(cos² θ−1/3)/2, and thus is a function of function and applied field.

The elasticity of solid materials is typically characterized by “Young's Modulus”, or the modulus of elasticity (E), which is defined as the ratio of an applied tensile or compressive stress and the resulting collinear strain, i.e., E=σ/ϵ. For a ferromagnetic material having λ_{S}≠0, this becomes: E=σ/(ϵₑ+ϵₘ). Ignoring temperature effects, E is thus seen to be a function of σ/ϵₑ, H, σ, λ_{S}, K₁, M_{S}, θ, and the respective peak values of previously applied stresses and fields.

### Mechanical Considerations

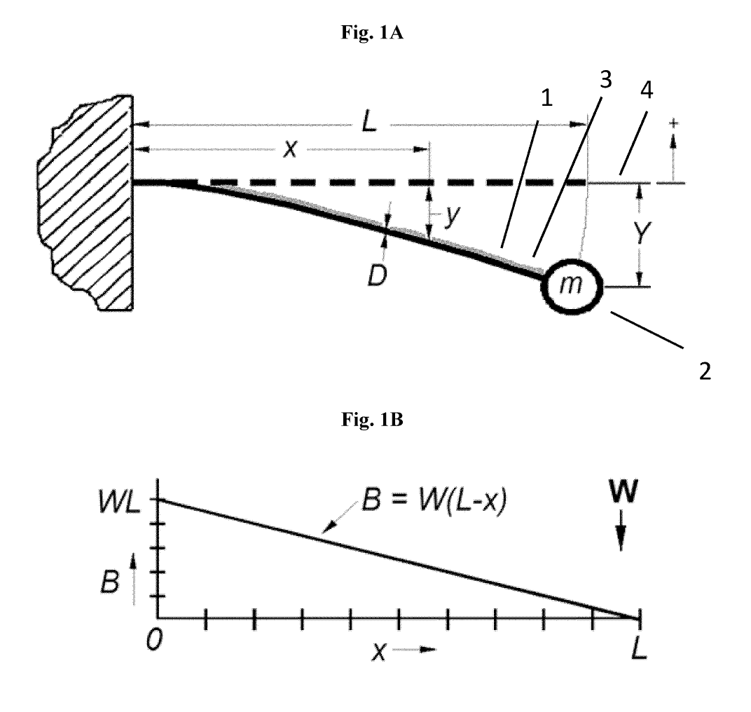

While the principles can be extended to more complicated geometry, for clarity of the explanation, a simple cantilever is shown in FIG. 1(a) and can be described by several parameters: A beam is shown, indicated by 1, composed of a material with modulus of elasticity E, is fixed at one end with length, L, that is typically long in relation to its width and thickness. The beam shown has either a uniform round (with diameter D) or rectangular cross section that is either solid or tubular, and optionally made as a composite material or having a surface treated with a compound (e.g., a binding reagent (e.g., an antibody, antigen-binding antibody fragment, receptor, enzyme, or the like) that specifically binds to a target analyte (e.g., an antigen, receptor ligand, enzyme substrate, etc.), as indicated by 3 (all of which for this purpose can be combined and represented by the moment of inertia, I). When a mass, m, as indicated by 2, is applied to the free end, which is acted upon by gravity producing a weight, W, and subsequent force, F, there is a deflection, y, from the nominal position of the beam without a force acting as indicated by 4, that is a function of distance from the fixed end of the beam, x. The bending moment can generally be calculated based on the applied loads and boundary conditions. This is also a function of the deflection of the beam, the modulus, and the moment of inertia as described by:

B=EₓIₓ(d²y/dx²) Equation 1

Equation 1 can be combined with relationships relating shear force, V, to the derivative of the bending moment, V=dB/dx, and distributed load, q, to the derivative of shear force, q=dV/dx. In cases of a prismatic beam (in which neither E nor I are functions of x), a method often referred to as the method of successive integrations can be used to solve for the deflection considering the distribution of loads and supports. In the case of a simple prismatic cantilever such as that shown in FIG. 1(a), the bending moment at any location, x, is the product of the force created by the weight, W, and the distance, (L−x), from where the force is applied, and is shown in FIG. 1 (b) as a function of x, such that Equation 1 can be solved through integration to find the deflection curve as:

y=W*x²/(6EI)*(x−3L) Equation 2

The deflection and stresses of more involved configurations of beams such as combinations of free, fixed, and guided ends of the beam under different loading conditions and statically indeterminate beam configurations can be found by solving for the distributed loads, shear, and bending moments as a function of the length of the beam, and solving Equation 1 either qualitatively, quantitatively or numerically, or by employing pre-solved tables solutions such as those in Roark's Formulas for Stress and Strain (Young, Budynas and Sadegh 2012, 125 to 380).

With respect to natural frequency, objects vibrate at a frequency or set of frequencies. For a system approximated by a weightless cantilever beam of fixed length, L, uniform and constant E, uniform cross section having moment of inertia, I, with an attached end mass, m=W/g, and stiffness, k (force per unit deflection=W/Y=3EI/L³ from Equation 2), the frequency of the primary mode of vibratory motion in radians will be found from (Inman 1996, 36) as:

f=1/√(k/m)=√((3EI)/(mL³)) Equation 3

In a body more complex than a simple cantilever, a system can vibrate in many ways, in which these different ways of vibrating each have their own frequency (modes of vibration) with the frequency determined by the moving mass in that mode and the restoring force which tries to return that specific distortion of the body back to its equilibrium position. As the modes are dependent upon the configuration, these modes can either be solved for qualitatively, quantitatively or numerically, or by again employing pre-solved tables solutions such as those in Roark's Formulas for Stress and Strain (Young, Budynas and Sadegh 2012, 765 to 768).

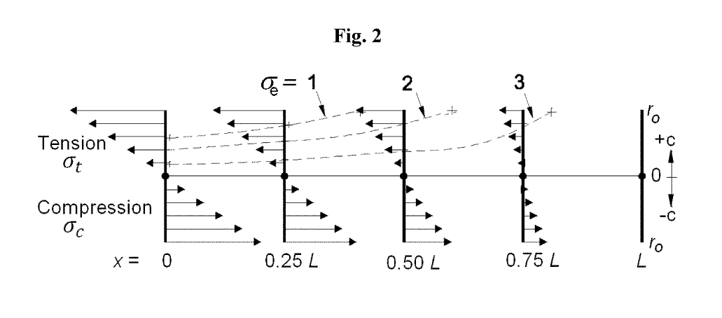

With respect to stress, static equilibrium of the beam member is maintained by oppositely directed, equal amplitude, bending moments acting on the cross sections at all locations along the beam length. These moments are the result of the symmetrical distribution of tensile and compressive normal stresses, σₜ, and σ_{c}, respectively shown in FIG. 2. The amplitude of σ on each cross section varies linearly with distance above (+c) and below (−c) the neutral axis (where σ=0) between limits determined by axial location (x) of the cross section. Its value is found from σ=Bc/I, commonly referred to as the flexure formula, where maximum absolute values of σ on each cross section are seen to occur where |c|=rₒ. It should be noted that the flexure formula is generally only considered valid where the stress distribution is not disrupted by changes in the shape of the beam or by discontinuities in the loading (Gere and Timoshenko 1997, 315 to 316).

### Effects of Conducted Current

It should first be noted that the following analysis neglects: time varying fields (skin depth), end effects of the beam (in particular considering cases in which the end conductors vary in size and spatial orientation), as well as material properties of the beam itself. The actual values and characteristics of the field versus geometry and time may well depend on values of physical properties of the beam material, which are expected to vary significantly with temperature, as well as frequency of the applied current. However, the following is useful for understanding the general phenomenon as well as provide an approximate indication as to how much current is required for a given field under hypothetical conditions.

Following from the relationship often called the “Biot-Savart Law”, an electrical current of i amperes conducted axially through a long, straight, round, solid conductor of homogeneous material, establishes a circumferential magnetic field having an intensity directly proportional to the enclosed current and inversely proportional to the radial distance from the conductor axis. Suitably accurate values of the field intensity in Oersteds at radial distances r cm from the axis of conductor of outside radius r₀ cm are determined from:

Hᵣ=2ir/(10 rₒ²) Equation 4

Unlike the continuous variation of σ with x shown in FIG. 2, radial variations of H are independent of x. Thus the effect of H (hence of i) is to induce a circumferential magnetization varying in amplitude from 0 at its axis, to a maximum at its surface, in a manner reflective of the MH characteristic of the beam material.

For non-circular beams, the calculation of the magnetic field from an applied current is not as simple but can be derived by integrating the vector potential of a line current ‘i’ from

$$A = \frac{{u}_{o}}{2 π} ilog ( r )$$

(where log is the natural log), combined with Stokes' theorem [symbol] A dl=∫_{A} B da, which expresses the line integral of vector potential to be equal to the magnetic field within the area enclosed. The line current can be integrated over the area of the beam. As an example, in the case of a rectangle of width 2*a, and thickness 2*b, the vector potential can be expressed at distance, r, as the integral of the line currents within the rectangle:

$$A = \frac{{Iu}_{o}}{8 π ab} {\int }_{- a}^{a} {\int }_{- b}^{b} log rd {x}^{′} d {y}^{′} \qquad Equation 5$$

The magnetic field can be found from the partial derivative of the vector potential according to:

$${H}_{x} = \frac{1}{{u}_{o}} \frac{\partial A}{\partial y} and {H}_{y} = \frac{1}{{u}_{o}} \frac{\partial A}{\partial x} \qquad Equation 6 ( a , b )$$

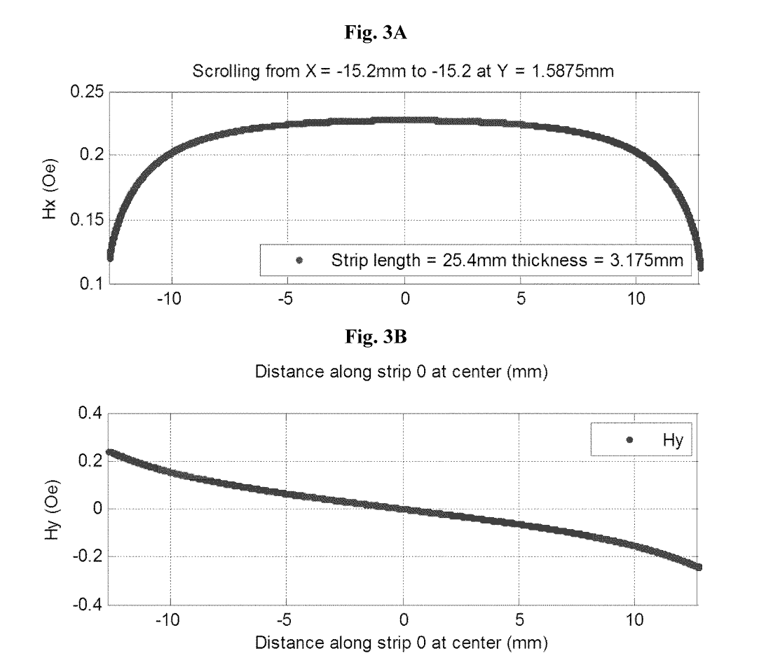

A sample plot of the calculated magnetic field for a rectangular conductor is shown in FIG. 3 for the provided dimensions. FIG. 3 (a) is a plot of the magnetic field in the direction of the width at the outer most surface of the conductor, and FIG. 3 (b) is a plot of the magnetic field in the direction of the thickness at the center of the conductor. As solving Equation 5 can be quite tedious, the magnetic field at several specific locations on the rectangular conductor can be conveniently expressed as follows:
Peak axial field at x=0 (center of rectangle) and y=b (thickness/2):

$${H}_{x} = \frac{I}{16 π ab} ( 2 a ( log ( 1 + 4 \frac{{b}^{2}}{{a}^{2}} ) ) + 8 b tan ( \frac{a}{2 b} ) ) \qquad Equation 7$$

Axial field at the side of the plate at x=a (side of rectangle) and y=b (thickness/2):

$${H}_{x} = \frac{I}{16 π ab} ( 2 a ( log ( 1 + \frac{{b}^{2}}{{a}^{2}} ) ) + 4 b tan ( \frac{a}{b} ) ) \qquad Equation 8$$

Radial field at side of plate at x=a (side of rectangle) and y=0 (center of plate):

$${H}_{y} = \frac{I}{16 π a} ( 2 b * log ( 1 + \frac{4 {a}^{2}}{{b}^{2}} ) ) + 4 a * a tan ( \frac{b}{2 a} ) ) \qquad Equation 9$$

### Stimulation of Motion

The following describes how the ΔE Effect can be used to stimulate motion of a beam under bending stress from an applied current. For clarity, the following explanation will generally refer to an example that uses a beam with a circular cross-section such that the circumferential field from applied current can be easily described by Equation 4. In the case of rectangular or more complicated cross-sections, the same principles are applicable; however, while the shape of the field will be more complex, it will still act to reorient the magnetization away from the longitudinal direction. For rectangular cross sections, the peak field from Equation 7 and Equation 8 can be used to provide a reasonable approximation as to the field acting to reorient the magnetization away from the longitudinal direction.

### Stress Anisotropy

Prior to the application of a bending moment or the conduction of a current longitudinally through the beam, the distribution of moment orientations (on a domain scale, but independent of polarity) is assumed to be isotropic for clarity of explanation. It is also assumed that this distribution is established by a random distribution of a structurally-based source of uniaxial anisotropy having energy density, U_{K}=K₁ sin² α, where α is the angle between K₁ and the magnetization, M. Considering materials in which λ_{S}≠0, a stress anisotropy, U_{σ}=3λ_{S}σ sin² θ/2, associated with the application of B, acts to bias the orientation distribution of M towards the longitudinal direction in regions where λ_{S}σ>0 and towards a transverse direction in regions where λ_{S}σ<0. “Biased” orientation distributions have a greater than average volume density of moment components having the orientation of the biasing source. In materials wherein the structural anisotropy has cubic rather than uniaxial symmetry, such bias may arise from displacement of 90° domain walls as well as by vector tilt. By either or both mechanisms, the bias in the orientation distribution of M will become more longitudinal with increasing +λ_{S}σ and less longitudinal with increasing |−λ_{S}σ|. For a beam configured as in FIG. 1(a), made of a material in which λ_{S}>0, the density of longitudinal components of |M| will decrease continuously from that at the upper surface to its value without a bending moment applied at the neutral axis. In like manner, the prevalence of transverse components will continuously grow in the region from the neutral axis to the lower surface. Following from the stress distribution shown in FIG. 2, the peak biases on each cross section will occur where c=rₒ, and the extrema of these peaks will occur where x=0.

### Magnetostatic Anisotropy

In similar fashion, a field H acts via the magnetostatic energy, U_{H}=−M_{S}H cos β to bias the orientation distribution of M with tangential components in cross sectional planes (β is the angle between M_{S} and H). With the field described by Equation 4, the effect of i is to create a region wherein the orientation distribution of M has a circumferential bias. This bias will be strongest at the surface, diminish to zero on the beam axis, and be independent of x (for long beams). Not significant here, but noted, is that the circumferential bias in M wrought by H also exhibits a single polarity.

### Strains, Curvature, and Deflection in Member

Recognizing that the curvature and resulting deflection (Gere and Timoshenko 1997, 303 to 309) of an initially straight beam, manifest the cumulative difference between the normal strains (i.e., those arising from the normal stresses), ΣΔϵ (hereafter), in regions respectively above and below the neutral surface of the beam, it becomes clear that changes in the magnitude of this difference will be mirrored in like sign changes in the deflection. Since the circumferential field from the axially conducted current acts to increase the circumferential component of ϵₘ in regions above and below the neutral surface, the advent of such a current is to reduce the difference in their respective normal strains. Thus it should be clear that consequential to the longitudinal conduction of i, there will be a reduction in ΣΔϵₘ, hence in ΣΔϵ, and most significantly, a reduction in Y, and thus a subsequent deflection. While the symbols ΣΔϵₘ and ΣΔϵ, have not been quantitatively defined, they, together with descriptive adjectives, e.g., large, larger, etc., will be found well suited to explain the phenomenon.

### Inducing Vibratory Motion

If the current driven magnetization changes more quickly than the deflection can be quasistatically reduced, the beam will exert an upward force in addition to W on the attached mass. This extra force originates primarily in those portions of the beams where the stable interatomic distances are most influenced by the magnetostriction, i.e., in the most highly stressed regions, particularly those where 3λ_{S}σ/2>0. Although these magnetoelastic influences on the distance between atoms will be reoriented as quickly as their moments are reoriented by the field, the inertia of the mass prevents equally fast changes in the beam deflection, hence in the normal strains, and ultimately in the parallel component of interatomic distances. Reorientation of the magnetoelastic influence thus leaves these distances in disequilibrium with their elastic binding forces, the consequence of which is the appearance of stresses in disequilibrium with the static bending moment. These stresses sum to an equilibrating force on the mass which is greater than its weight, i.e., F>W=W+ma, where a is its acceleration acting in the opposite direction of the force (and subsequent stresses and strains) causing the deflection. (Newton's First Law asserts the need for an externally applied force to create or alter the motion of a massive body. Although deriving from the described internal causes, and the inertia of the mass at the movable end of the beam, the forces driving the observed vibratory motion are ultimately provided by the reaction force and force couple acting between the fixed end of the beam and its “points of attachment” to the “earth”.) The gathering momentum (=∫madt, wherein t is time) of the now moving mass will carry it farther upward than if by quasistatic position adjustment. The described events manifest a well understood physical effect wherein the peak deflections and associated strains and stresses arising from a force which is suddenly applied to an undamped system, reach twice the magnitude as compared to the same quasistatically applied force (Inman 1996, 119 to 120). Being above its equilibrium position i.e., that which can be maintained in equilibrium between the bending moment and the deflection curve or by the stresses and strains or ultimately by the bonding forces and the interatomic distances, the net force exerted by the beam on the mass is less than W; the mass begins to move downward. By virtue of its now downward momentum it will overshoot its equilibrium location. If i is reduced to zero at some time during this downward motion, the reorientation of ϵₘ to its alignment with ϵₑ will, in the previously described manner, act to further the downward motion. It should now be obvious that, by turning the current on and off at times synchronized with the motion of the mass, the extremes of upward and downward motion can be made to grow. In terms of ΔE, a vibratory motion will have been induced by the periodic alteration of E in resonance with the natural period of a mass/elastic system.

### Forcing Function

While the inventors typically used a single ‘pulse’ of current to provide a change in strain and subsequent deflection, any arbitrary excitation that acts as a forcing function to the beam should be considered applicable to the invention, including pulse width modulated (PWM) excitation currents. The current can be controlled using feedback of a sensed parameter; sensed parameters are not limited to but include the measurement of: position at a specific location of the beam, a force or stress acting on the beam of hardware supporting the beam, or through the use of the deflection to provide a change in capacitance or inductance. Alternatively, the current can be applied open loop, in which the input might be (i) periodic with time, or (ii) be a spectrum (such as white or distributed noise), which might allow the output to be analyzed and characterized as a function of the input over a wide range of frequencies.

### Deflection is Function of Stress and Field

Without a difference in the magnetoelastic portions of strain, ϵₘ, on each side of the beam's neutral axis for an applied current to act on, there will be no deflection; and likewise, to the limits defined by the material characteristics and saturation magnetostriction, the greater the stress, the more the applied magnetization will act to reorient the magnetization and thus magnetoelastic strain, ϵₘ, such that there will be more deflection. This is important for several reasons:
(i) A beam without a bending stress applied will not deflect regardless of the magnetic field applied (not considering other ΔE effects, Lorentz forces, etc.). The stress could be internal to the beam (e.g. residual stress), but there must be some stress for the field to act on to produce deflection.
(ii) As the deflection is a function of both the applied stress and applied current, then the amount of stress that is applied is a function of the deflection, such that deflection or parameters related to deflection of the member might be measured to provide a measurement indicative of the stress.

### Experimental Validation

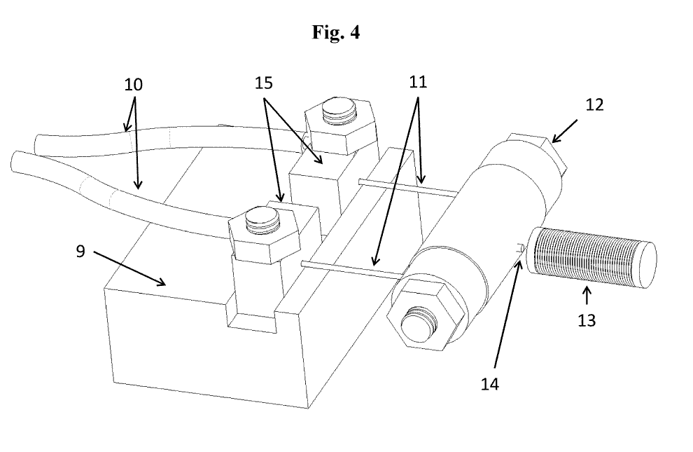

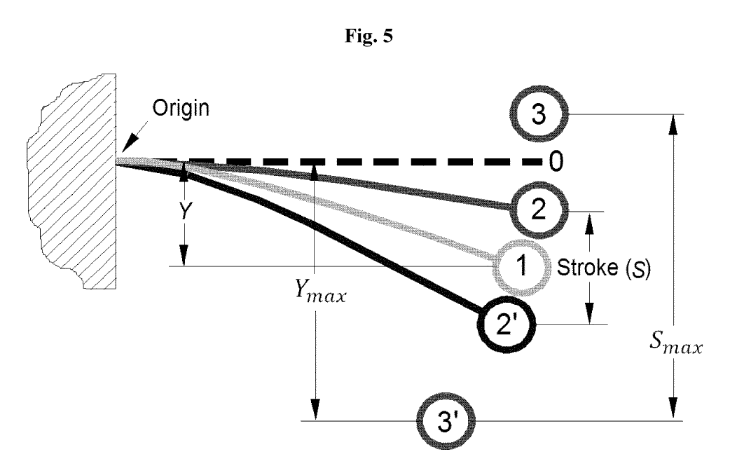

For validation of the theory used by the inventors, a schematic diagram of the apparatus is illustrated in FIG. 4. The apparatus employed two parallel, equal sized cantilevered beams, 11, which were fixed and clamped at one end to conductive fixtures, 15, which allowed current to be applied via conductors indicated by 10, in which the fixtures, 15, were screwed to a phenolic (non-conductive) base, 9. A cantilevered mass, 12, was used to apply stress to the beams as well as close the path of current through the cantilever. The configuration was selected over others for several reasons: It fixes the plane of each beams' deflection; avoids incidental torsional loading, and avoids the need to make flexible wire connections. In this embodiment, the position of the beam was detected using a small magnet, 14, placed on the cantilevered mass, 12, such that a pickup coil, 13, could be used to measure the rate of change of position of the mass. Other preferred embodiments use an optical displacement sensor based on an emitter/detector pair, or use a laser based system to measure position. The beams, 11, were tested in varying lengths (ranging from 20 mm to 100 mm), geometries (circular beams typically less than 1 mm diameter, and rectangular beams typically less than 0.5 mm by 2 mm), and materials described but not limited to those below. The displacement of the cantilever was quantified by stroke, defined as “S” as shown in FIG. 5. With a force applied by the mass, the beam did not have any deflection, such that end was located at position ‘0,’ and with a force the end of the beam would be at position ‘1.’ When oscillating, the beam would be centered about position ‘1,’ but reach positive and negative extrema as defined by position ‘2’ and ‘2′’, and ‘3’ and ‘3′.’

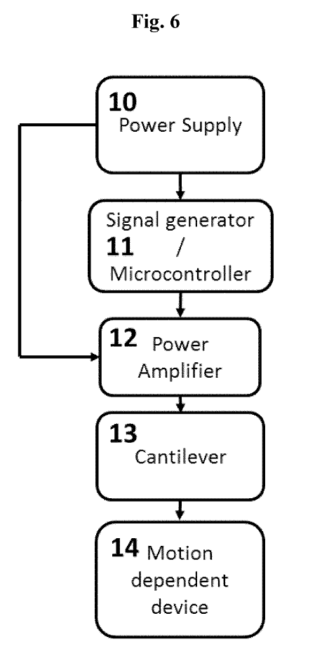

A flow diagram for an open-loop setup is shown in FIG. 6, in which a power supply, indicated by 10, was used to provide power to a signal generator, 11 (a device that produces an electrical waveform, the frequency, shape, and amplitude of which can be varied), in which the output was amplified through a power amplifier, 12. The synchronously varying electric current would then be conducted through the series connected twin beams, indicated by 13, also illustrated in FIG. 4. Current of selected wave shape and peak amplitude, e.g., half sinewave, unipolar triangular or rectangular pulses, etc., of frequency, fₘ, obtained from a simple apparatus (i.e., a function generator and appropriate amplifiers) was initially employed. When synchronously varying electric current was conducted, vibration of the cantilever was confirmed by measuring the emf induced in the pickup coil based on the change of position of the magnet, indicated by 14 in FIG. 4, relative to the pickup coil, as indicated by 13 in FIG. 4, and by the presence of visible motion of the cantilevered beams. Visible motion could be induced by synchronously varying electric current in beams fabricated from Kanthal 70 (70Ni 30Fe), λ_{S} 16 ppm, saturation magnetization 1047 emu/cm³, K1 700 J/m³), Kulgrid 27 (100Ni shell, 100Cu Core, λ_{S}−40 ppm, saturation magnetization 480 emu/cm³, K1−3400 J/m³), Vacoflux 50 (49Co 49Fe 2V, λ_{S} 70 ppm, saturation magnetization 1870 emu/cm³, K1 2000 J/m³), and electrical steel (3SiFe, λ_{S} 6 ppm). Stroke as defined by “S” as shown in FIG. 5, in which motion was visible when the measured stroke was >˜0.3 mm. It was also apparent that attainment of continuous beam vibration was relatively insensitive to current waveshape (or waveform) details other than its frequency (fᵢ). Current waves varying from zero to peak values of a few amperes and returning to zero (or some comparatively small reverse value) during (>5% to <50%) of 1/f could with great certainty initiate and maintain detectable primary mode vibrations in beams of these materials.

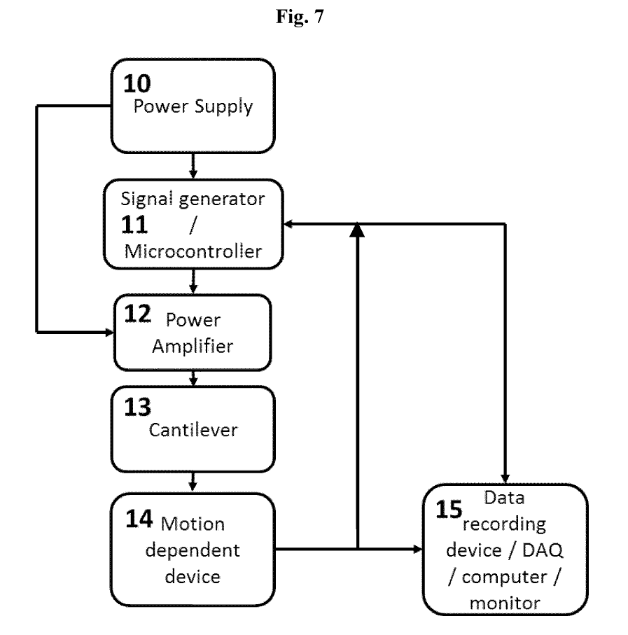

The inventors found obtaining a motion signal that can be used for feedback to energize the beam at a desired interval to be an important element in regards to obtaining consistent amplitude of vibration. As illustrated by the flow chart in FIG. 7, a feedback system was implemented in which the motion signal, 14, was fed back through a data acquisition system and computer. In this configuration, the signal generator, 11, could be replaced by the computer/data acquisition system, 15, and fed directly to the power amplifier, 12.

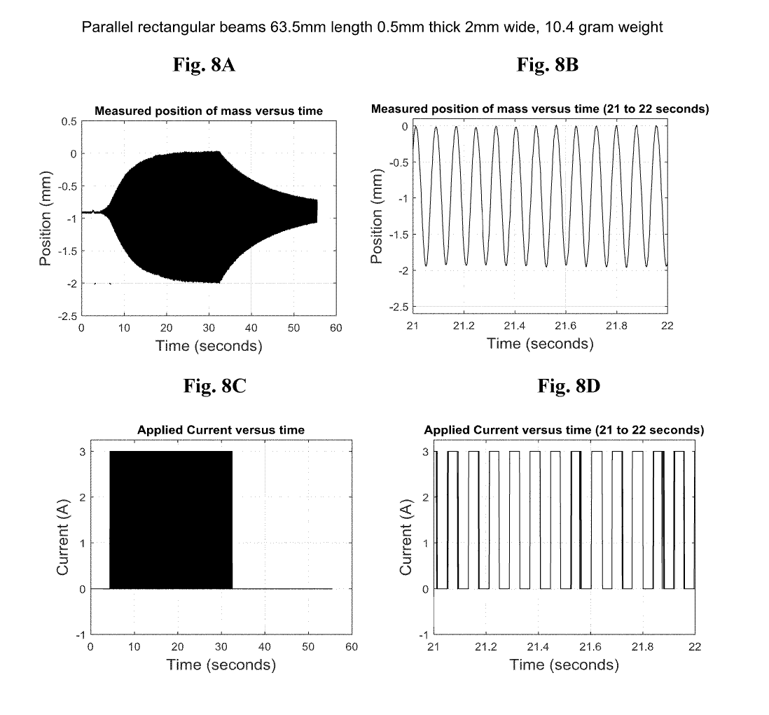

As shown in FIG. 8 are four plots using feedback and data acquisition system described by FIG. 7, in which current was applied to a parallel cantilever setup such as that shown in FIG. 4. Feedback was based on an optical position sensor measuring the position of the mass, in which the controller was configured to apply electrical current when the position of the cantilever was beneath the neutral axis, and the mass was moving upwards toward the neutral axis. The beams had a rectangular cross section of 0.5 mm×2 mm, and were manufactured from grain oriented Silicon Steel rolled in the longitudinal direction (beams rolled in the transverse direction were also tested). FIGS. 8 (a) and (c) show the full run, in which current is first applied and the stroke continues to increase and approach steady-state conditions, until the application of current is halted, in which the stroke is seen to decrease. FIGS. 8 (b) and (d) zoom into 21 to 22 seconds to show the oscillatory features of interest, being a sinusoidal shape motion that can be characterized by frequency and amplitude (stroke).

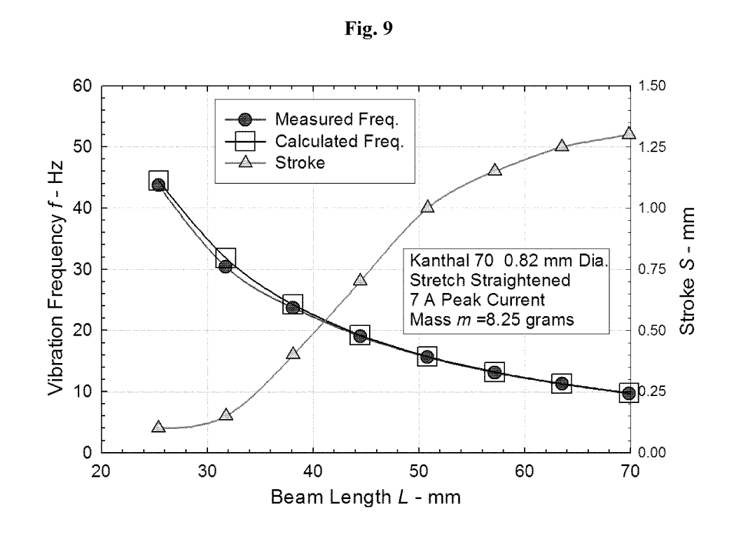

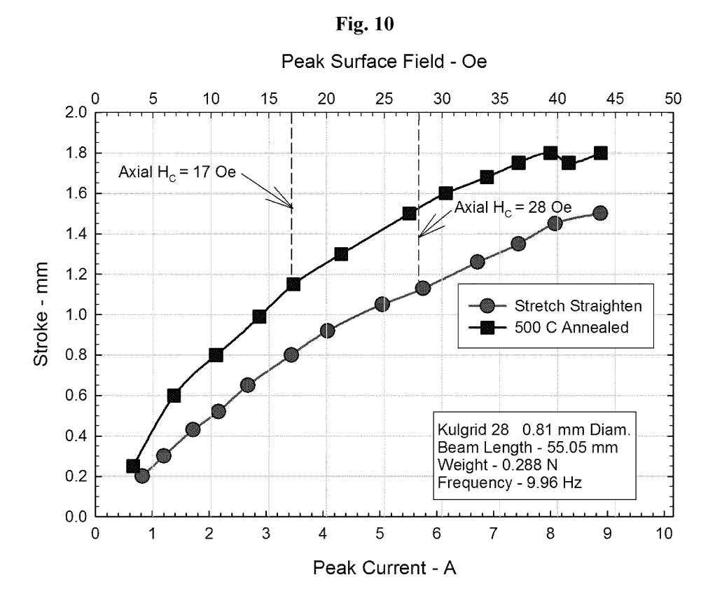

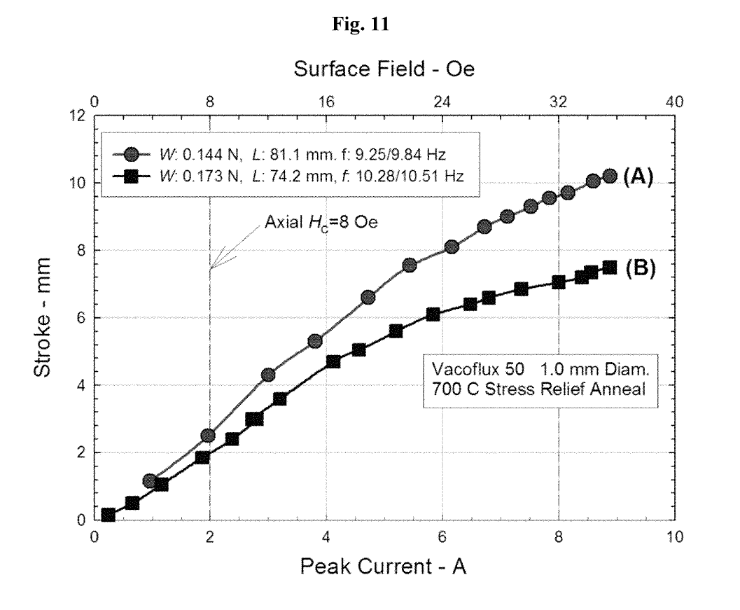

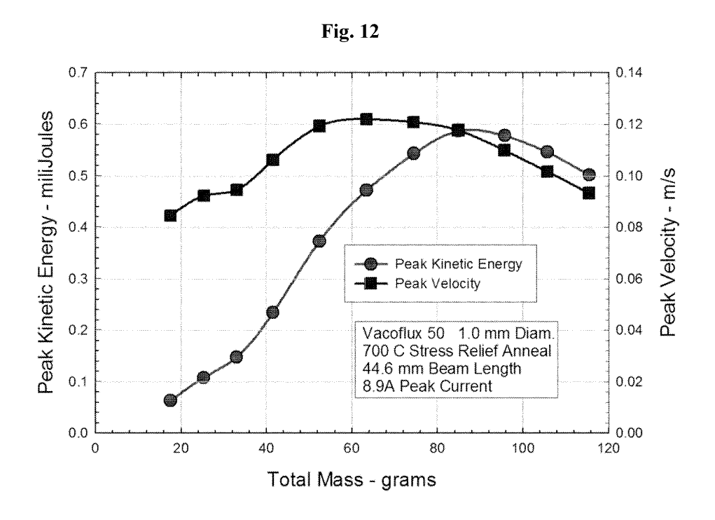

The characteristics of vibration frequency and stroke are plotted for Kanthal 70 (with a circular cross section) in FIG. 9, in which the measured frequency is plotted along with the calculated frequency (based on beam length, moment of inertia, and mass), in which stroke is also plotted versus beam length for a set current of 7 Amperes being applied. FIG. 10 plots stroke versus peak current for Kulgrid 28 in two different conditions, stretched and straightened versus annealed at 500 degrees Celsius, which indicates that greater strokes are obtained for greater currents. FIG. 11 plots stroke versus peak current for Vacoflux 50 for two different lengths and weights. FIG. 12 plots peak kinetic energy and peak velocity versus total mass for Vacoflux 50.

The absence of detailed reports on the phenomenon being explored, together with the recognition that synchronously varying forces of electromagnetic origin (Lorentz Forces) also act on current carrying conductors, which are immersed in an ambient magnetic field (e.g., from the earth) suggested the need to test materials wherein M_{S} and/or λ_{S} are nominally zero. Paramagnetic copper and AISI 302 stainless steel (18Ni 8Co, λ_{S} 0 ppm, saturation magnetization 0 emu/cm³, K1 0 J/m³), both meet these conditions. It was not found possible to either stimulate or maintain (after mechanical stimulation) detectable vibrations in beams of either of these materials by the conduction of electric currents, varying at or near fₘ, 0.5 fₘ, or slowly varying over random ranges, using wave shapes and peak amplitudes, which were universally successful with the 3 magnetostrictive materials. Other aspects of the test results with materials in which vibration was detected: 1) motion characteristics independent of current polarity; 2) changes in the effect of current amplitude on amplitude of motion with changes in beam's material or with changes in the properties of any one sample material (e.g., by annealing); 3) the fact that motion could not be produced with copper beams but was readily produced with nickel clad copper beams (Kulgrid); and 4) beams of HyMu 80 (4Mo 80Ni, λ_{S˜}0 ppm, saturation magnetization 692 emu/cm³, K1˜0 J/m³), a high permeability, near zero λ_{S} and K₁ material appeared to take longer to fully extinguish mechanically initiated vibration when accompanied by the synchronously varying current than without such current, however quantitative comparisons with identically started vibrations were not attempted; leave no remaining doubt that the motion attained in the described manner is produced by magnetoelastic (i.e., not electromagnetic) phenomena. While the range of materials was limited, the effects are expected to be present for magnetostrictive materials with crystal anisotropy suitably low enough that the applied current is able to produce a magnetic field that is sufficient to reduce or eliminate the component of magnetoelastic strain.

### Motion Signals

As described in the ‘Experimental Validation’ section, the inventors found obtaining a motion signal that for feedback to energize the beam at a desired interval is an important element in regards to obtaining consistent amplitude of vibration as illustrated with the flow chart in FIG. 7. The frequency of vibration of cantilevered beams, such as that described by Equation 3 is very sensitive to the geometry of the beam as well as the mass. As changes in temperature can result in changes in geometry, the natural frequency consequently changes. The inventors initially used an open loop excitation, but found motional feedback to be very useful as the excitation signal would track the natural frequency to ensure the input current is synchronized with the motion to produce an optimal deflection.

### External Motional Sense Signals

There are many methods to obtain a signal that is indicative of the deflection of the beam. To name several, but not being limited to:
the magnet and pickup coil (as was used by the inventors),
an optical method such as a light or laser based positioning method (also used by the inventors),
capacitance such as that measured between the vibrating plate and a parallel plate,
a strain sensitive element such as a strain gauge attached to the beam,
an accelerometer that might be placed on the cantilever or on a member supporting the cantilever,
an LVDT that might be in direct contact with part of the beam.

### Internal Motional Sense Signals

The inventors observed that the conductors carrying current might also serve to provide for a means of measuring the motion. This was expected as the beam was remanently magnetized by the applied current in the circumferential direction such that deflection was acting to reorient the remanent circumferential magnetization. Just as Faraday's law describes a voltage induced in a circumferential loop of wire proportional to the rate of change of flux enclosed by the loop, so too does it predict a voltage induced in a (straight) wire proportional to the rate of change of circumferential magnetization.

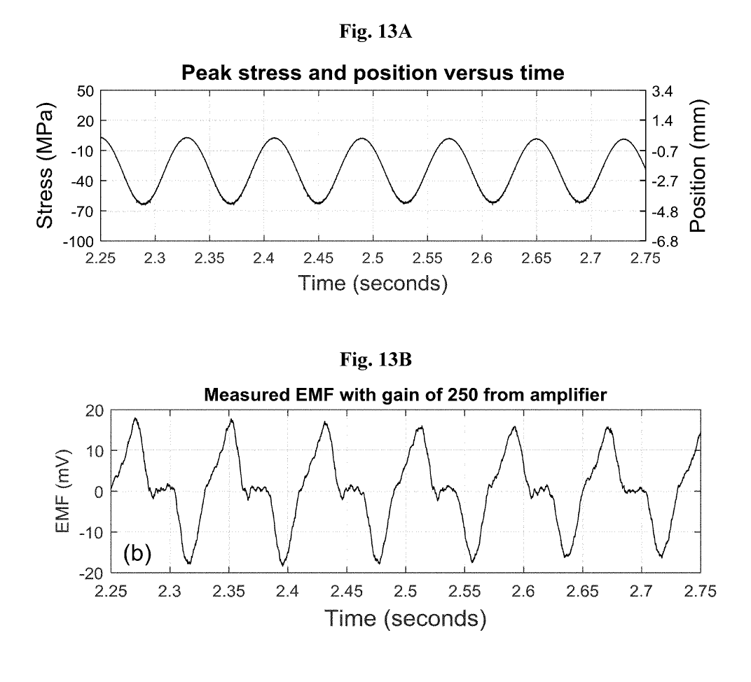

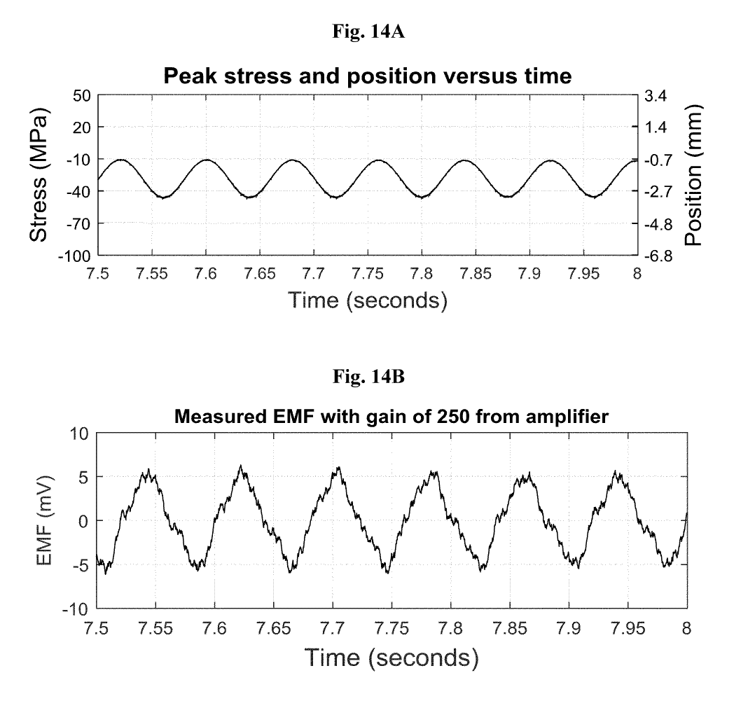

Shown in FIG. 13 are two plots, in which FIG. 13 (a) is a plot of position of the mass measured in millimeters with an optical displacement sensor, and peak stress calculated from the measured position and the beam geometry; the peak stress occurs at the fixed end of the beam and at the outermost position from the neutral axis as indicated in FIG. 2. In FIG. 13 (a), it can be seen that the position of the beam is returning approximately to the neutral axis, where the stress is minimal. FIG. 13 (b) is a plot of the emf measured using an instrumentation amplifier with a gain of 250 and recorded with a 16-bit oscilloscope. The primary frequency component of the measured emf is seen to be the same as that of the frequency of motion, in which there is a periodic signature feature in which the emf is negligible (corresponding to the maximum stress acting on the shaft). As per Faraday's law, the emf corresponds to the rate of change of magnetization, which indicates that when the emf is negligible, there is not a significant change of magnetization (or all change in magnetoelastic strain has been realized). FIG. 14 contains two plots, comparable to FIGS. 13 (a) and (b), but several seconds later such that the amplitude of the oscillation has been reduced through damping. In this case, the periodic signature feature in which the emf is negligible is not discernible. These plots indicate there is a measureable signal with features that are a function of stress that might be used to provide a signal indicative of the motion of the cantilever.

### EXAMPLES

### Variations of Cantilever Construction

The invention is applicable to any constructions in which an applied conducted current is used to change a portion of the magnetoelastic strain originating from bending stress and thus the deflection along the length of the cantilever. Examples of these constructions were previewed in Mechanical Considerations, and include configurations of beams that use combinations of free, fixed, and guided ends, under different loading condition, which include ‘statically indeterminate’ beam configurations.

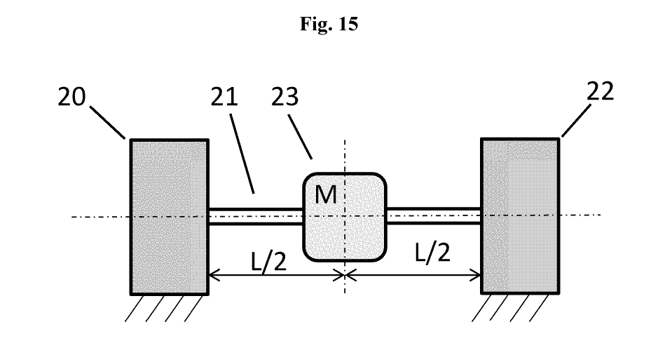

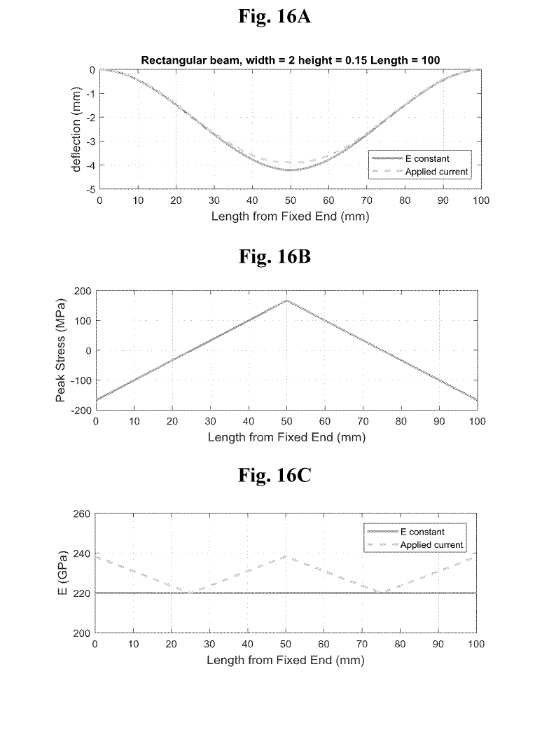

FIG. 15 illustrates how the invention can be applied to beam configurations other than the simple cantilevers shown in FIG. 1 and FIG. 4. FIG. 15 contains cantilever, 21, fixed at both ends, as indicated by 20 and 22, with mass, indicated by 23, significantly greater than the weight of the cantilever itself (a similar analysis could be completed in which the sole mass is the cantilevered beam itself, or the mass of the cantilever is not negligible). If an applied current is conducted from 20 to 22 through cantilever 21, sufficient to reduce a portion of the magnetoelastic strain, the stress along the beam will remain the same as governed by the applied load; however along the length of the beam the total strain will vary with applied current and stress. As the modulus of the material, E, is a function of stress and strain, it will effectively vary along the length of the beam. Shown in FIG. 16, are three plots. FIG. 16 (a) shows the deflection curve with and without applied current (changing a portion of the magnetoelastic strain), FIG. 16 (b) is a plot that indicates that the stress is the same along the length, regardless of whether or not current is applied, and FIG. 16 (c) is a plot showing E as a function of the length of the beam. This embodiment demonstrates how this invention is also applicable to a simple wire supported between two points. A similar analysis could be completed for different beam configurations: e.g. one fixed end and one guided end, two guided ends, etc., in which stress will vary with the length of the beam, and applied current will reduce a portion of the magnetoelastic strain producing a change in the deflection curve.

It is also an embodiment of the invention that the cross-section of the beam might also vary as a function of the distance along the beam. For particular embodiments, it may be advantageous to use a variable cross-section (acknowledging the cost of manufacturing such a beam is likely to be greater), as it may allow the stress and deflection to be optimized across the length of the beam for a particular configuration. For example, considering the stress versus distance from the fixed end, x, such as that shown in FIG. 16 (b), the stress is smallest at L/4 and 3 L/4. To optimize the deflection curve, the cross section of the beam might be reduced either by changing the radius (of a circular beam), or changing the width, thickness, or even shape of a non-circular or rectangular beam (e.g. adding a slot), as a function of the length.

It is also an embodiment of the invention to use a multiplicity of beams. For particular embodiments, it may be advantageous to use beams that are: stacked vertically, rigidly connected at each of their respective ends, at some point other than their ends, or are composite beams that are joined together along their length. These beams may be electrically isolated, or electrically connected: at one end, or configured to act to transmit current in parallel or in series. These arrangements allow embodiments with beams that may independently provide excitation and sensing. Optionally, the geometry of the beams may be configured such that the subsequent deflection and/or difference in the deflection between beams (the gap) can serve to provide a sensed parameter that is dependent upon deflection (such as using a capacitive measurement between the beams). Optionally, a multiplicity or composite beam may also be configured to apply an effective bending stress to both beams (such as that if the beams or beam materials have dissimilar lengths or are made with a dissimilar coefficient of thermal expansion in which the temperature is changed). As an example of a composite beam, Kulgrid 27, described in the Experimental Validation section is a cylindrical composite beam with a Nickel shell and Copper core. Composite beams might also include the use of piezoelectric, ferrous, and non-ferrous materials.

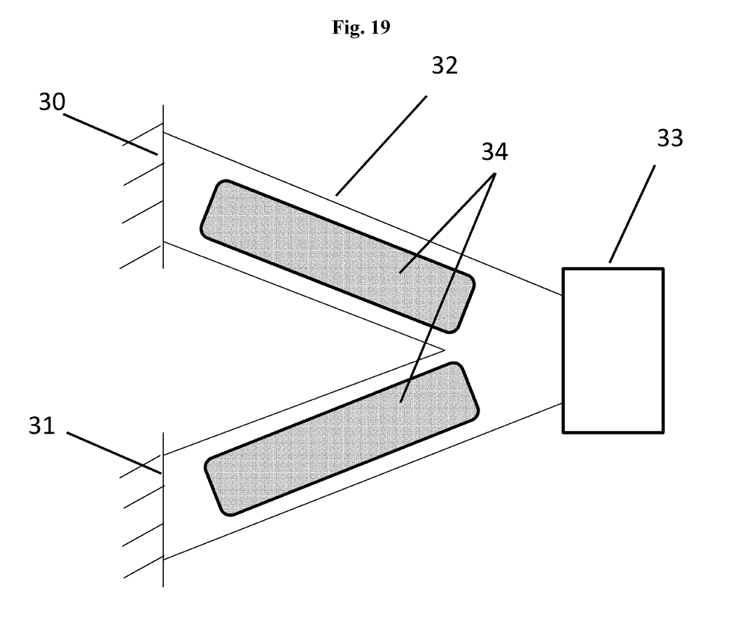

It is also an embodiment of the invention that configurations include beams that are connected in series, or may use a variety of shapes, including but not limited to ‘V’ shapes (such as shown in FIG. 19 as will be discussed in section ‘Cantilevers in sensing applications’), ‘Y’ shapes, star shapes, etc. Such configurations might be used to control the path of current, amplify the total deflection, stress, or provide other features for transducer purposes such as to carry out a function (e.g. perform work as an actuator), or be used as a feedback mechanism. Beams might be connected in series, to provide functions such as allowing for one section of the beam to be used for inducing motion, and another for sensing, or connected in such a way that one beam is used to apply stress to another (such as connecting two beams of different lengths to induce a bending stress).

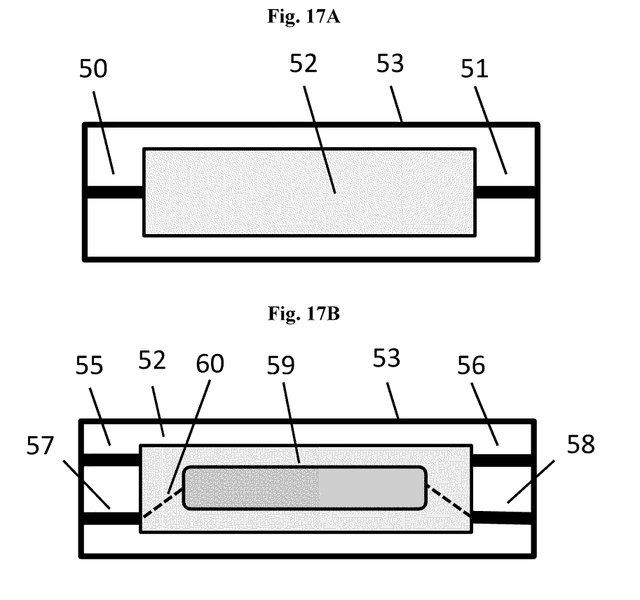

It is also an embodiment of the invention that the beam might be a portion of a bigger structure. For example, a multiplicity of beams might be supporting a cantilevered mass within a frame such as that shown in FIGS. 17 (a) and (b) (which is a fairly typical construction for an accelerometer), in which current can be conducted across any variety of beams. For example, in FIG. 17 (a), from 50 to 51, and FIG. 17 (b) from 55 to 57 and 56 to 58, or from 55 and 57 to 56 and 58 etc. With respect to an embodiment of an accelerometer, in which there is a larger mass located within a frame that acceleration acts on, it is common that motion is detected using a capacitive measurement between the mass 52 and the frame 53, or optionally an isolated region within the mass as indicated by 59, in which an electrical connection might still be made as indicated by 60.

The following examples demonstrate how different configurations of cantilevers can allow the described invention to be applied to varied applications. Although not necessarily described in each embodiment, it is an object of the invention that the emf induced in the cantilever itself from the oscillatory deflection might optionally serve as either an input to be used for feedback or also as an output signal.

### Mechanical Applications

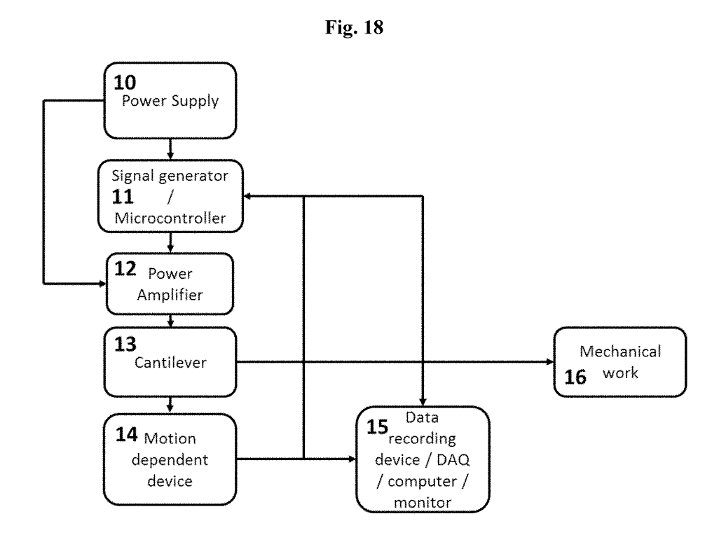

To illustrate the operating principles of the basic invention as applied to an actuator/pumping embodiment, reference is given to FIG. 18, block 16. As indicated by FIG. 18, blocks 10 to 14 represent the method of generating motion, in which block 15 represents the motion might be acquired with an acquisition system such as a computer. Block 16 is a configuration that allows this motion to be harnessed to carry out mechanical work, in which this work might include pumping a fluid. An example that such an embodiment of this invention is applicable to is described by U.S. Pat. No. 3,963,380. This work describes the use of a microfluidic pump that uses a piezoelectric effect to drive variable volume chambers to facilitate the function of pumping. The basic invention might be carried out to serve this function, as cantilevered beams could be used to produce the deflection and thus change the volume of the variable volume chambers inducing fluid flow, allowing for the cantilevered beams to be comprised of a high strength ferromagnetic material potentially allowing for a greater compression of the volume chambers and thus greater flow of fluid.

While the following are not common uses of existing cantilever embodiments, it is conceivable that the motion induced in a cantilever based on changing a portion of magnetoelastic strain with an applied current, might be used in mechanical actuator embodiments. Examples of such embodiments would be the use of a cantilever to: (i) rotate a shaft by coupling the deflection of the cantilever through the use of a one-way clutch, (ii) produce linear motion, in which deflection is used to exert a force and subsequent displacement on a rack, or (iii) use the displacement of the cantilever to actuate a valve. The invention might also use the natural frequency of the cantilever to build up energy and then act to unload its stored kinetic energy periodically as part of the operation of a machine (e.g. the mass periodically hits an object to carry out a function). An example of the energy that can be built up within an oscillating cantilever is shown in FIG. 12. Other examples of embodiments the invention might be used in include mechanical configurations that act to stir or mix a medium, or in the use of a mechanism configured to counter-act unwanted vibration, such as an active-damping system.

### Cantilevers in Sensing Applications

To illustrate the operating principles of the basic invention as applied to a sensing embodiment that is configured to sense the presence of targeted compounds, reference is given to FIG. 19. The cantilever, 32, in this embodiment is configured in, but not limited to, being configured in a ‘V’ configuration, with optional mass, 33, fixed at ends 30 and 31, which also act to serve as the location of the conductors used to apply conducted current through the cantilever. The cantilever can be treated along a surface, indicated by 34, or on the mass itself, with a chemically selective compound such that targeted molecules, vapors, biomarkers, proteins, etc., bind or are accumulated on the treated surface. When there is an accumulation of target chemicals or compounds on the cantilever, the cantilever will experience a surface stress causing a bending stress and subsequent deflection in the cantilever, as well as change in oscillating mass.

If the full cantilever, portion of the cantilever, or composite portion of the cantilever, is manufactured from a material with magnetoelastic properties, the bending stress and subsequent strain will have a magnetoelastic component, in which the bending stress originates from the accumulation of the targeted compounds. If there is a change in the magnetoelastic strain from applied conducted current, there will be a subsequent change in the deflection curve of the cantilever. The deflection can be measured through an external parameter that is configured to be dependent upon the deflection, including but not limited to optical or capacitive methods, in which this parameter can be used as a measurement of the bending stress and thus the accumulation.

To illustrate the operating principles of the basic invention as applied to a frequency change embodiment, the mode of fabrication is the same; however attention will be paid to the change in oscillating mass based on accumulation of target chemicals or compounds. Such as that described by Equation 3, the resonance frequency is a function of the mass and length of the beam, as well as the modulus of the beam, E. As the effective oscillating mass of the beam changes, so too will the resonance frequency. If the applied current is configured to stimulate oscillatory motion at the natural frequency of the system, measuring the change in resonance frequency through any of the parameters based on deflection also allows the measured parameter to be used as an indicator as to the amount of accumulation. The change in frequency and thus the amount of accumulation acting on the cantilever can be measured through an external parameter that is configured to be dependent upon the deflection, including but not limited to optical, magnetic (using a magnet and sense coil), or capacitive methods. Optionally, this parameter can be the emf induced within the cantilever itself as described in section ‘Internal motional sense signals.’

### Flow Measurement

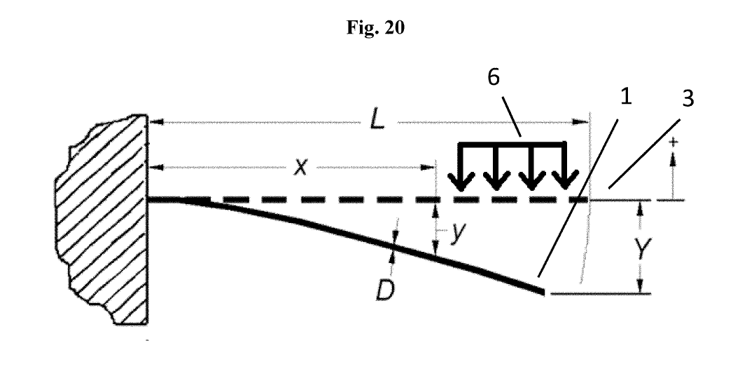

To illustrate the operating principles of the basic invention to a flow measurement embodiment, reference is given to FIG. 20. Should the cantilever, 1, be placed in a flow, 6 (or distributed load), a bending stress and subsequent deflection comprised of both elastic and magnetoelastic strains will be present, in which the bending stress will be a function of the flow rate (and density of the fluid). If an applied current is conducted through the cantilever, the magnetoelastic strain will be reduced causing a change in the deflection of the cantilever. It is an object of the invention, that as the bending stress increases (as per the application of an increased flow rate), so too would the change in strain and subsequent deflection for a given applied current, such that a measurement of the change in deflection curve can provide an indication as to the magnitude of flow rate (or density of the fluid) acting on the cantilever.

### Discrete Measurement Embodiments

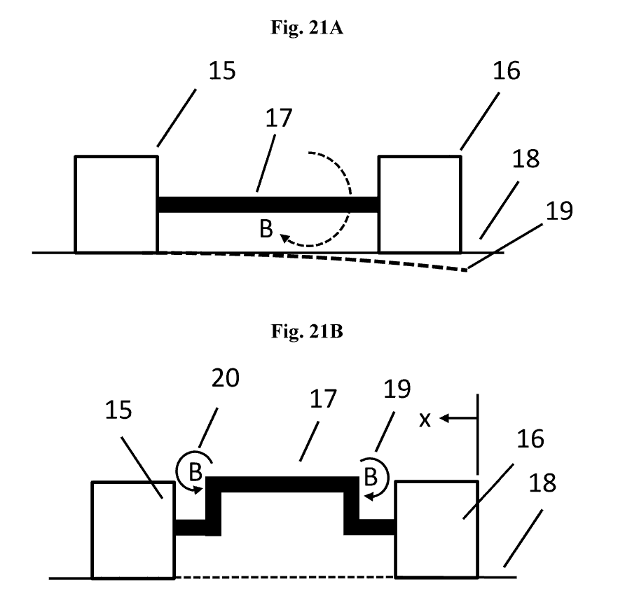

To illustrate the operating principles and applicability of the invention to an embodiment that can measure bending or linear strain on a separate member, reference is given to FIG. 21 (a). A cantilever, 17, is located between two fixtures 15 and 16, configured either to prevent deflection and a change in slope of the cantilever (such as if the end is fixed), or optionally to prevent deflection but not slope (such as through the use of a pin). Fixtures 15 and 16 are fixed to a separate member, 18, through a bonding method such as using fasteners, clamps, or bonding agents. As member 18 undergoes bending stress, it will deflect to position 19, which will also apply a deflection and bending stress, represented by 14, to cantilever 17 (assuming that the stiffness of the cantilever is small as compared to the member it is mounted). If an applied current is conducted from 15 to 16 through cantilever 17, a portion of the magnetoelastic strain will be reduced, producing a change in the deflection curve of 17 (even though ends 15 and 16 are constrained), such as that described in section ‘Variations of cantilever construction.’ Measuring a parameter associated with change in deflection when current is applied will be a function of the bending stress on the separate member, 18.

Another embodiment of the invention is shown in FIG. 21 (b), in which the cantilever is designed to produce a bending moment, indicated by 19, from a linear deflection such as that indicated by 20, in which the distance between 15 and 16 is varied (as would be applied due to a linear strain on member 18, in which the stiffness of the cantilever is small as compared to the member it is mounted). If an applied current is conducted from 15 to 16 through 17, and there is a magnetoelastic strain component present based on the linear deflection as indicated by 20, a portion of the magnetoelastic strain will be reduced, producing a change in the deflection curve of 17. While the end points of the cantilever at 15 and 16 are constrained, the deflection curve across 17 will be changed. Measuring a parameter associated with change in deflection when current is applied will also be a function of the change in deflection from 15 to 16.

### Dynamic Measurement

As an object of the invention, and applicable but not limited to the previously described embodiments, there may be significant advantages in regards to improved signal to noise ratios by using properties of the invention to stimulate dynamic motion in the cantilever. Applied to the prior example, ‘Cantilevers in sensing applications,’ if the cantilever, 17, is driven with an applied current that is a function of its resonance frequency (in which the resonance frequency could be configured to be significantly higher than the measurement frequencies of interest, such as greater than 50,000 Hertz), the peak-to-peak amplitude at the resonance frequency or frequency modes depending upon the configuration, would be dependent upon the applied stress. As such, filtering, frequency modulation, and/or utilizing ratios of amplitudes at frequency modes, might allow deflection to be measured with a significantly better signal to noise ratio as compared to measuring a static value alone. This might allow for the use of the invention in an embodiment that might be considered an ‘active sensor’ system.

### Practical Variations

As described were several examples in which the invention might be immediately applicable, but considering the countless examples and embodiments in which cantilevers are used, it should be considered that the invention is applicable to any arrangement of beams in which conducted current is used to reduce a component of magnetoelastic strain originating from bending stress. Any means of applying stress to the beam or combination thereof should be considered applicable to the invention. Examples of sources of stress are but are not limited to:
Beams with a weight supported at one end.
Beams with a load or force distributed across its length (or portion thereof) or a mass acting at one or more point along the length of the beam.
The weight of the beam itself acting in gravity.
Surface stresses acting on the beam, such as those that are caused by a treatment applied to the beam, in which targeted compounds bind to the cantilever, or compounds that are applied that change with time, temperature, etc. that result in a surface stress.
Residual stress within the beam itself.
Motion of the beam itself that produces stress within the beam.

As the invention describes a basic mechanism by which current conducted through the beam produces a field that changes a component of strain along a portion of the length of the beam, the invention is applicable to one or more beams in any configuration that satisfies this mechanism to induce motion. It may be advantageous to tailor the beam design and/or forcing function(s) to maximize the change in the component of strain with respect to the input power. As the maximum stress and thus maximum magnetoelastic strain is a function of the length, cross section of the beam (the maximum stress occurs farthest from the neutral axis), and the loading configuration of the cantilever (e.g. the maximum stress is proximate to the fixed end of a simple cantilever), practical embodiments and methods may be tailored to ensure the magnetic field produced from current produces the maximum change in magnetoelastic strain while minimizing losses. Examples of these embodiments and methods include but are not limited to: (i) the use of forcing functions that employ Eddy currents that act to limit the penetration depth of the current and magnetic field, (ii) the use of composite materials that have an increased conductivity farther away from the neutral axis (e.g. the outer diameter of the shaft) and decreased conductivity closer to the neutral axis, or (iii) the use of a beam design that minimizes material that is at a lower stress both along the length of the beam and closer to the neutral axis (e.g. such as through the use of a hollow shaft).

All of the devices, articles, systems, and methods described and claimed herein can be made and executed without undue experimentation in light of the present disclosure. While the devices, articles, systems methods of this invention have been described in terms of preferred embodiments, it will be apparent to those of skill in the art that variations may be applied to the articles and methods without departing from the spirit and scope of the invention. All such variations and equivalents apparent to those skilled in the art, whether now existing or later developed, are deemed to be within the spirit and scope of the invention as defined by the appended claims. It will also be appreciated that computer-based embodiments of the instant invention can be implemented using any suitable hardware and software.

All patents, patent applications, and publications mentioned in the specification are indicative of the levels of those of ordinary skill in the art to which the invention pertains. All patents, patent applications, and publications are herein incorporated by reference in their entirety for all purposes and to the same extent as if each individual publication was specifically and individually indicated to be incorporated by reference in its entirety for any and all purposes.

The invention illustratively described herein suitably may be practiced in the absence of any element(s) not specifically disclosed herein. Thus, for example, in each instance herein any of the terms “comprising”, “consisting essentially of”, and “consisting of” may be replaced with either of the other two terms. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically described by preferred embodiments and optional features, modification and variation of the concepts herein disclosed may be resorted to by those skilled in the art, and that such modifications and variations are considered to be within the scope of this invention as defined by the appended claims.

### BIBLIOGRAPHY

Bozorth. Ferromagnetism. Piscataway, N.J.: IEEE Press, 1993.
Cullity, B. D., and C. D. Graham. Introduction to magnetic materials. Hoboken, N.J.: IEEE/Wiley, 2009.
Gere, J. M., and S. P. Timoshenko. Mechanics of Materials. Boston: PWS Publishing Company, 1997.
Guillemin, A. Compes Rendus 22 (1846): 264 to 265, 432.
Inman, D. J. Engineering vibration. Englewood Cliffs, N.J.: Prentice Hall, 1996.
Joule, J P. “On the Effects of Magnetism upon the Dimensions of Iron and Steel Bars.” The London, Edinburgh and Dublin philosophical magazine and journal of science, no. 30, Series 3 (1842): 76-87, 225-241.
Meyer, E, Hans J. Hug, and Roland Bennewitz. Scanning probe microscopy: the lab on a tip. Berlin, N.Y.: Springer, 2004.
Tumanski, Slawomir. Handbook of Magnetic Measurements. CRC Press, 2011.
Young, Warren C., Richard C. Budynas, and Ali M. Sadegh. Roark's Formulas for Stress and Strain. New York, N.Y.: McGraw-Hill, 2012.

1. An actuator, comprising:
(a) at least one flexurally stressible member comprised of a ferromagnetic, electrically conductive, non-zero magnetostriction material, wherein the member is configured to bend about its neutral axis in a deflection curve upon application of a force to the member; and
(b) one or more electrical conductors or electrical conductor leads to provide electrical communication between the member and a power supply.

2. An actuator according to claim 1 that is connected to a power supply, wherein the power supply optionally includes a controller to control delivery of electrical energy from the power supply to the member or a portion thereof at a desired interval or range of intervals.

3. An actuator according to claim 1 wherein the member is (i) a cantilevered beam comprising spaced proximal and distal ends, wherein the proximal end is secured to a substrate; or (ii) a beam comprising spaced proximal and distal ends, wherein the beam is attached to one or more substrates at one or more locations between its proximal and distal ends.

4. An actuator according to claim 3 wherein the member is comprised of a plurality of (i) cantilevered beams each having its proximal end secured to the same or a different substrate; (ii) beams each attached to one or more substrates at one or more locations between each beam's respective proximal and distal ends; or (iii) beams attached beam-to-beam.

5. An actuator according to claim 1 wherein the member comprises bending stress or residual stress.

6. An actuator according to claim 3 wherein the beam further comprises a weight secured thereto at a mounting position spaced from the substrate, wherein the mounting position is optionally about 0.01× to about 1× the length of the beam.

7. An array comprising a plurality of actuators according to claim 1, wherein each actuator is optionally independently addressable.

8. A sensor, comprising:
(a) at least one transducer comprised of a flexurally stressible member comprised of a ferromagnetic, electrically conductive, non-zero magnetostriction material, wherein the member is configured to bend about its neutral axis in a deflection curve upon application of a force to the member;
(b) one or more electrical conductors or electrical conductor leads to provide electrical communication between the transducer and a power supply;
(c) a power supply to energize the member at a desired interval or range of intervals in order to induce movement in the member, wherein the power supply further optionally comprises or is connected to a signal generator to generate electrical signals to be input into the member that, when output from the member, can be analyzed to sense a change in a measurable parameter of the transducer; and
(d) a computer configured to detect a change in the transducer or a measurable parameter of the transducer, optionally movement or a change in movement of the transducer, through analysis of electrical signals output by the transducer or of a sensible parameter associated with the transducer.

9. A sensor according to claim 8 wherein the power supply optionally includes a controller to control delivery of electrical energy from the power supply to the member or a portion thereof at a desired interval or range of intervals.

10. A sensor according to claim 8 wherein the member is (i) a cantilevered beam comprising spaced proximal and distal ends, wherein the proximal end is secured to a substrate; or (ii) a beam comprising spaced proximal and distal ends, wherein the beam is attached to one or more substrates at one or more locations between its proximal and distal ends.

11. A sensor according to claim 8 wherein the member is comprised of a plurality of (i) cantilevered beams each having its proximal end secured to the same or a different substrate; or (ii) beams each attached to one or more substrates at one or more locations between each beam's respective proximal and distal ends.

12. An array comprising a plurality of sensors according to claim 1, wherein each transducer is optionally independently addressable.

13. A method of generating movement in a member of an actuator, comprising energizing the member(s) of an actuator according to claim 1 one or more times, wherein when the member is energized more than once, energizing the member occurs at a desired interval or range of intervals.

14. A sensing method, comprising using a sensor according to claim 8 and detecting changes in the transducer, optionally movement or a change in movement of the transducer, through analysis by the computer of electrical signals output by the transducer or of a sensible parameter associated with the transducer.

15. A control method, comprising using a sensing method according to claim 14 and further using the computer to control the power supply to adjust the desired interval(s) at which the member is energized in order to obtain desired movement of the member, wherein the computer is further configured to use results of the analysis to control movement of the member.

16. A sensor, comprising:
(a) an transducer according to claim 8; and
(b) a computer configured to detect a change in a measurable parameter of the member(s), optionally movement or a change in movement of the member(s), through analysis of signals output by the transducer.

17. A sensing method, comprising using a sensor according to claim 16 and detecting changes in the transducer, optionally movement or a change in movement of the transducer, through analysis by the computer of signals output by the transducer.

18. A control method, comprising using a sensing method according to claim 17 and further using the computer to control a power supply powering the sensor to adjust the desired interval(s) at which the member is energized in order to obtain desired movement of the member, wherein the computer is further configured to use results of the analysis of signals output by the transducer or of a sensible parameter associated with the transducer to control movement of the member.
